(19) United States
(12) Patent Application Publication
(10) Pub. No.: US 2006/0051497 A1
(43) Pub. Date: Mar. 9, 2006

(54) Process for preparing organic electroluminescent device

(76) Inventors: Yuji Hamada, Ikoma-gun (JP); Hiroshi Kanno, Osaka-city (JP); Kazuki Nishimura, Hirakata-city (JP)

Correspondence Address: MCDERMOTT WILL & EMERY LLP, 600 13TH STREET, N.W., WASHINGTON, DC, 20005-3096, US

(21) Appl. No.: 11/085,233

(22) Filed: Mar. 22, 2005

(30) Foreign Application Priority Data
Mar. 31, 2004 (JP) 2004-106377

(51) Int. Cl. B05D 5/06; B05D 5/12

(52) U.S. Cl. 427/66

(57) ABSTRACT

A process for preparing an organic electroluminescent device in which a hole transporting layer, a first light emitting layer, and a second light emitting layer are disposed between a pair of electrodes, the first light emitting layer contains at least one dopant material and host material and, the host material is the same compound as a hole transporting material of the hole transporting layer, characterized in that the hole transporting layer and the first light emitting layer are continuously formed in the same chamber.

The priority Japanese Patent Application Number 2004-106377 upon which this patent application is based is hereby incorporated by reference.

### BACKGROUND OF THE INVENTION

1. Field of the Invention

The present invention relates to a process for preparing an organic electroluminescent device.

2. Description of the Related Art

An organic electroluminescent device (organic EL device) is being actively developed from a viewpoint of application to a display and illumination. A driving principle of an organic EL device is as follows. That is, a hole and an electron are injected from a hole injecting electrode and an electron injecting electrode, respectively, and these are transported in a carrier transporting layer made of an organic material, and recombined in a light emitting layer etc., thereby, excited state is generated in a light emitting material, and emitting is obtained from this excited state.

There is provided an organic EL device in which a light emitting layer is formed of a host material and an emitting dopant material, and a light emitting efficiency is enhanced by effectively transferring excitation energy from a host material to an emitting dopant (JP-A No. 2003-77676 etc.). In addition, an attempt has been tried to dispose a blue emitting layer and an orange emitting layer as a light emitting layer to obtain a white emitting organic EL device.

An organic material layer such as a light emitting layer and a carrier transporting layer is generally formed by a vacuum deposition method. Formation of each layer by a vacuum deposition method is generally performed in a chamber, but formation of a plurality of layers in the same chamber, and the kind of layer preferably formed in the same chamber etc. have not been studied in detail.

### SUMMARY OF THE INVENTION

An object of the present invention is to provide a process for preparing an organic EL device which can remarkably improve life property.

The present invention is a process for preparing an organic EL device in which a hole transporting layer, a first light emitting layer, and a second light emitting layer are disposed between a pair of electrodes, the first light emitting layer contains at least one dopant material and host material and, the host material is the same compound as a hole transporting material of a hole transporting layer, characterized in that the hole transporting layer and the first light emitting layer are continuously formed in the same chamber.

In the organic EL device in the present invention, as a host material contained in a first light emitting layer, the same compound as a hole transporting material of a hole transporting layer is used. In the present invention, the hole transporting layer and the first light emitting layer consisting of the same compound like this are continuously formed in the same chamber. By continuously forming the hole transporting layer and the first light emitting layer in the same chamber, surprisingly, light emitting life property of an organic EL device can be remarkably improved.

Regarding the reason why better life property is obtained by continuously forming a hole transporting layer and a first light emitting layer in the same chamber in the present invention, details are not clear, but it is contemplated that, since an interface between a hole transporting layer and a first light emitting layer is formed in the better state by continuously forming in the same chamber, deterioration of organic materials in a light emitting layer and a hole transporting layer hardly occurs. That is, in the present invention, hole transporting materials such as an arylamine-based compound, a representative of which is NPB as a triarylamine-based compound are contained in a hole transporting layer and a first light emitting layer, and these hole transporting materials easily undergo influence of oxygen, water, and the like which are adsorbed on a surface. For this reason, when oxygen, water, and the like are adsorbed onto an interface between a hole transporting layer and a first light emitting layer, phase change easily occurs at an interface and, for this reason, there is a possibility that organic materials are changed by a chemical reaction. Since such the adsorption of oxygen, water, and the like at an interface can be prevented by continuously forming a hole transporting layer and a first light emitting layer in the same chamber according to the present invention, it is contemplated that deterioration of organic materials in a light emitting layer and a hole transporting layer hardly occurs.

In the present invention, by forming an orange emitting layer as a first light emitting layer, and forming a blue emitting layer as a second light emitting layer, a white emitting organic EL device can be obtained. In the orange emitting layer, a triarylamine derivative can be used as a host material, and since this triarylamine derivative is a hole transporting material, this can be used to form a hole transporting layer.

In the present invention, a hole transporting layer and a first light emitting layer are continuously formed in the same chamber. When these layers are formed by a vacuum deposition method, they can be formed by changing a deposition source by opening and closing a lid of a deposition source in a chamber. In this case, since a host material and a hole transporting material are the same compounds, the same deposition source may be used as a deposition source for these compounds.

By continuously forming a hole transporting layer and a first light emitting layer in the same chamber according to the present invention, an organic EL device excellent in life property can be prepared.

### BRIEF DESCRIPTION OF THE DRAWINGS

FIG. 1 is a cross-sectional view showing a structure of an organic EL device manufactured in Example in accordance with the present invention.

### DESCRIPTION OF PREFERRED EXAMPLES

The present invention will specifically explained below by way of Examples, but the present invention is not limited to the following Examples.

### Example 1

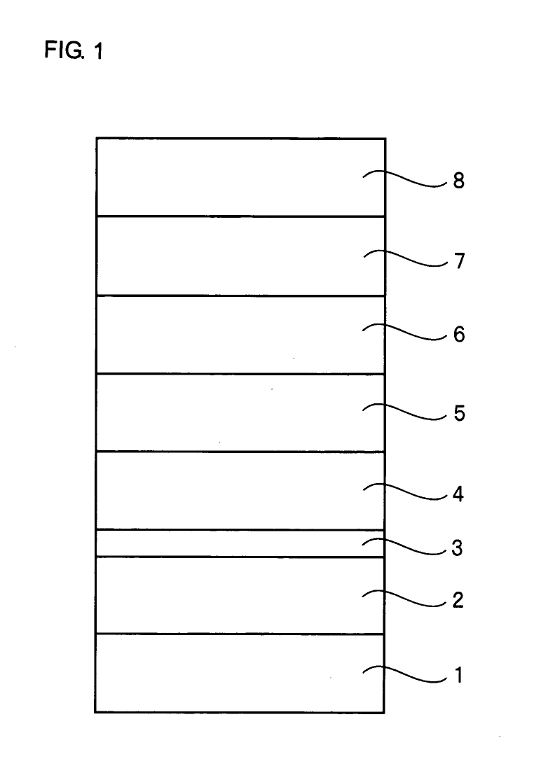

An organic EL device having a structure shown in FIG. 1 was manufactured. Referring to FIG. 1, a hole injecting electrode consisting of ITO is formed on a substrate 1, and a hole transporting layer 4 (thickness 240 nm) consisting of NPB is disposed on a hole injecting electrode 2. An orange emitting layer 5 (thickness 30 nm) and a blue emitting layer 6 (thickness 40 nm) are disposed on a hole transporting layer 4. An electron transporting layer 7 (thickness 30 nm) consisting of Alq is formed on a blue emitting layer 6. An electron injecting electrode 8 consisting of LiF (thickness 1 nm) and Al (thickness 250 nm) is disposed on an electrode transporting layer 7.

In the orange emitting layer 5, NPB is used as a host material, 3% by weight of DBZR is used as an emitting dopant material, and 20% by weight of tBuDPN is used as a carrier transporting dopant.

In the blue emitting layer 6, TBADN is used as a host material, 2% by weight of TBP is used as an emitting dopant material, and 7% by weight of NPB is used as a carrier transporting dopant material.

A hole injecting layer 3 consisting of CFx was formed by a plasma CVD method. Each layer other than it was formed by a vacuum deposition method.

As shown in Table 1, a hole transporting layer 4 and an orange emitting layer 5 were continuously formed in a chamber A. A blue emitting layer 6 was formed in a chamber B, and an electron transporting layer 7 was formed in a chamber C.

### Example 2

As shown in Table 1, a hole transporting layer and an orange emitting layer were continuously formed in a chamber A, and a blue emitting layer and an electron transporting layer were continuously formed in a chamber B.

### Comparative Example 1

As shown in Table 1, a hole transporting layer was formed in a chamber A, an orange emitting layer and a blue emitting layer were continuously formed in a chamber B, and an electron transporting layer was formed in a chamber C.

### Comparative Example 2

As shown in Table 1, a hole transporting layer was formed in a chamber A, an orange emitting layer was formed in a chamber B, and a blue emitting layer and an electron transporting layer were continuously formed in a chamber C.

### Comparative Example 3

As shown in Table 1, a hole transporting layer was formed in a chamber A, an orange emitting layer was formed in a chamber B, a blue emitting layer was formed in a chamber C, and an electron transporting layer was formed in a chamber D.

Organic materials used in forming respective layers are as follows:
NPB is N,N′-di(1-naphthyl)-N,N′-diphenylbenzidine, and has the following structure; 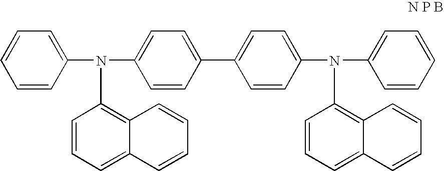
   DBzR is
5,12-bis{4-(6-methylbenzothiazol-2-yl)phenyl}-6,11-diphenyl naphthacene, and has the following structure; 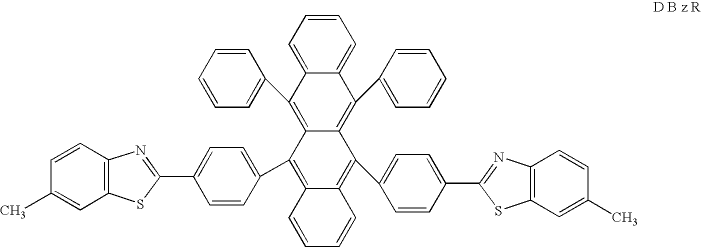
tBuDPN is 5,12-bis (4-tertiary-butylphenyl) naphthacene, and has the following structure; 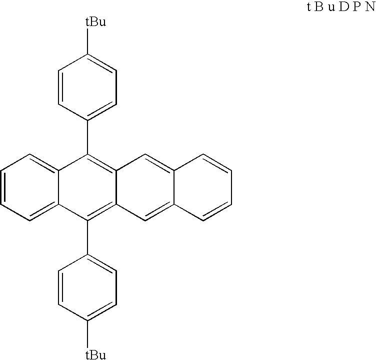
   TBADN is
2-tertiary-butyl-9,10-di(2-naphthyl)anthracene, and has the following structure. 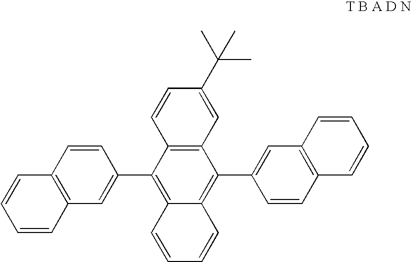
   TBP is 2,5,8,11-tetra-tertiary-butylperylene, and has the following structure;

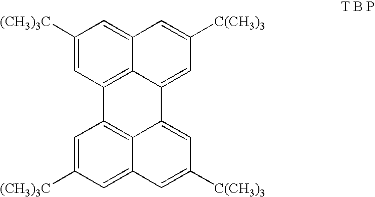

Alq is tris-(8-quinolilato)aluminum (III), and has the following structure;

TABLE 1

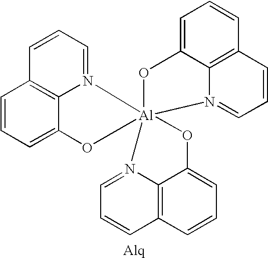

| | Chamber A | | Chamber B | Chamber C |
|---|---|---|---|---|
| Ex. 1 | Hole | Orange Emitting Layer | Blue Emitting Layer | Electron |
| | Transporting | | | Transporting |
| | Layer | | | Layer |
| | NPB(240) | NPB + 3% DBzR + 20% tBuDPN(30) | TBADN + 2% TBP + 7% NPB(40) | Alq(30) |
| | Chamber A | | Chamber B | |
| Ex. 2 | Hole | Orange Emitting Layer | Blue Emitting Layer | Electron |
| | Transporting | | | Transporting |
| | Layer | | | Layer |
| | NPB(240) | NPB + 3% DBzR + 20% tBuDPN(30) | TBADN + 2% TBP + 7% NPB(40) | Alq(30) |
| | Chamber A | Chamber B | | Chamber C |
| Comp. | Hole | Orange Emitting Layer | Blue Emitting Layer | Electron |
| Ex. 1 | Transporting | | | Transporting |
| | Layer | | | Layer |
| | NPB(240) | NPB + 3% DBzR + 20% tBuDPN(30) | TBADN + 2% TBP + 7% NPB(40) | Alq(30) |
| | Chamber A | Chamber B | Chamber C | |
| Comp. | Hole | Orange Emitting Layer | Blue Emitting Layer | Electron |
| Ex. 2 | Transporting | | | Transporting |
| | Layer | | | Layer |
| | NPB(240) | NPB + 3% DBzR + 20% tBuDPN(30) | TBADN + 2% TBP + 7% NPB(40) | Alq(30) |
| | Chamber A | Chamber B | Chamber C | Chamber D |
| Comp. | Hole | Orange Emitting Layer | Blue Emitting Layer | Electron |
| Ex. 3 | Transporting | | | Transporting |
| | Layer | | | Layer |
| | NPB(240) | NPB + 3% DBzR + 20% tBuDPN(30) | TBADN + 2% TBP + 7% NPB(40) | Alq(30) |

[Assessment of Organic EL Device]

Regarding respective organic EL devices of Examples 1 and 2 as well as Comparative Examples 1 to 3, an emitting efficiency, a driving voltage, and a life (half life) were measured. The measurement results are shown in Table 2.

TABLE 2

| | Emitting | Driving | Emit- | Life | |
|---|---|---|---|---|---|
| | Efficiency | Voltage | ting | (Half Life) | |
| | at 20 mA/cm² | at 20 mA/cm² | Color | at 5000 cd/m² | |
| Ex. 1 | 13.0 cd/A | 7.0 V | White | 2200 | hr |
| Ex. 2 | 13.2 cd/A | 6.9 V | White | 2300 | hr |
| Comp. Ex. 1 | 11.6 cd/A | 7.0 V | White | 1100 | hr |
| Comp. Ex. 2 | 11.6 cd/A | 7.1 V | White | 1050 | hr |
| Comp. Ex. 3 | 11.5 cd/A | 6.9 V | White | 900 | hr |

As apparent from results shown in Table 2, organic EL devices of Examples 1 and 2 obtained by continuously forming a hole transporting layer and an orange emitting layer in the same chamber A according to the present invention show 2-fold or longer life property as compared with organic EL devices of Comparative Examples 1 to 3. As apparent from comparison with Comparative Examples 1 to 3, in continuous formation of an orange emitting layer and a blue emitting layer, and continuous formation of a blue emitting layer and an electron transporting layer, the effect of the present invention is not obtained and, it is seen that life property is specifically improved only when a hole transporting layer and an orange emitting layer are continuously formed.

What is claimed is:

1. In a process for preparing an organic electroluminescent device in which a hole transporting layer, a first light emitting layer, and a second light emitting layer are disposed between a pair of electrodes, the first light emitting layer contains at least one dopant material and host material and, the host material is the same compound as a hole transporting material of the hole transporting layer,
said process for preparing an organic electroluminescent device characterized by continuously forming the hole transporting layer and the first light emitting layer in the same chamber.

2. The process for preparing an organic electroluminescent device according to claim 1, wherein the first light emitting layer is an orange emitting layer, and the second light emitting layer is a blue emitting layer.

3. The process for preparing an organic electroluminescent device according to claim 1, wherein the hole transporting layer and the first light emitting layer are continuously formed by changing a deposition source by a vacuum deposition method.

4. The process for preparing an organic electroluminescent device according to claim 1, wherein the hole transporting material and the host material are a triarylamine derivative.
